(19) United States
(12) Patent Application Publication
(10) Pub. No.: US 2010/0243019 A1
(43) Pub. Date: Sep. 30, 2010

(54) SOLAR ENERGY CONCENTRATOR

(75) Inventor: Stefan Larsson, S-Alvkarleby (SE)

Correspondence Address: DRINKER BIDDLE & REATH (DC), 1500 K STREET, N.W., SUITE 1100, WASHINGTON, DC, 20005-1209, US

(73) Assignee: Stefan LARSSON, S-Alvkarleby (SE)

(21) Appl. No.: 12/739,068

(22) PCT Filed: Oct. 21, 2008
(86) PCT No.: PCT/SE2008/051182

§ 371 Date: May 25, 2010

(30) Foreign Application Priority Data
Oct. 22, 2007 (SE) 0702374-0

(51) Int. Cl. H01L 31/058; H01L 35/02

(52) U.S. Cl. 136/230; 136/248; 136/246

(57) ABSTRACT

The present invention comprises an arrangement adapted for an absorption of primarily thermal and/or luminous energy arising from received sunbeams, and having a sunbeam-reflecting reflector unit faceable toward the sunbeams and a thermal and/or luminous energy-absorbing means related to the reflector unit, said reflector unit and said thermal and/or luminous energy-absorbing means being coverable by a transparent protection, said reflector unit, in particular the reflector surface thereof, being formed from a thin and easily bendable material. Said reflector unit and primarily the upper reflector surface thereof is adapted for a co-operation with a plurality of discrete support members, denominated “reflector spring”, distributed along a length-oriented or longitudinal extension of said reflector unit and the upper reflector surface thereof, and oriented perpendicularly to, or at all events substantially perpendicularly to, said longitudinal extension, in order to allow said reflector unit and/or reflector surface to, depending on a temperature influence, be able to deform within an elastic range applicable for selected shape and/or choice of material, however while keeping a profile of a stable shape.

### TECHNICAL FIELD OF THE INVENTION

The present invention generally relates to an arrangement that goes under the designation “a solar energy concentrator”.

More particularly, the present invention intends to suggest an arrangement and a unit, which in manifold, oriented in rows and columns, will be able to utilize a part of the thermal and/or luminous energy carried by sunbeams.

Accordingly, the present invention intends even more particularly to allow to provide an arrangement adapted for an absorption of primarily thermal energy arising from received sunbeams, and having a sunbeam-reflecting reflector unit faceable toward the sunbeams and a thermal and/or luminous energy-absorbing means related to the reflector unit.

Said reflector unit and said heat-absorbing means should advantageously be able to be coverable by a protection, transparent to sunbeams and light, wherein said reflector unit and the reflector surface thereof should be formed from a thin and easily bendable material and have a light-reflecting reflector surface, prepared to present a high reflection factor.

### BACKGROUND OF THE INVENTION

Methods, arrangements and designs related to the above-mentioned technical field and nature are previously known in a plurality of different embodiments.

In this connection, by mathematical calculations, it is known to allow to create a curved reflector surface, which makes that incident sunbeams will be able to converge toward a focal point, in order to there afford an increased heat concentration.

In solar cells and/or solar energy concentrators, having a length-oriented or longitudinal extension, it is then known to allowing focal points to form a focal segment or line for an absorption of heat within an elongate medium, such as a water/glycol mixture.

There are also known different constructions for a utilized heat-absorbing means, where it, on one hand, has been provided a possibility of allowing to transform the generated thermal energy, in the form of light beams, into a heated water current, and on the other hand it has been provided a possibility of allowing to transform the generated thermal energy, in the form of light beams, into an electrical energy, while utilizing a plurality of opto-electric converters.

Opto-electric converters are found in different embodiments and have lately become the subject of an intense development, in order to allow to increase the efficiency thereof.

In this technical area, it is also known to mount the solar cells and/or the solar energy concentrators on a turnable foundation, in order to, via different circuitry arrangements and control equipments, constantly allow to turn the solar cell or the solar energy concentrator in a direction toward incident sunlight and tip or tilt the solar cell and the reflecting surface thereof perpendicularly to incident sunlight beams.

As an additional example of prior art and the technical area to which the invention relates, it may be mentioned an arrangement adapted for an absorption of primarily heat arising from received sunbeams, and having a sunbeam-reflecting reflector surface faceable toward the sunbeams and a thermal and/or luminous energy-absorbing means related to a reflector unit, said reflector unit and said thermal and/or luminous energy-absorbing means being coverable by a protection, transparent to sunlight and resistant against mechanical action and/or damage, wherein said reflector unit, and particularly the reflector surface thereof, should be formed from a thin and easily bendable material.

To the prior art, also a solar energy concentrator box or container belongs, shown in the Swedish Utility Model Registration 79 604, based on the Swedish Utility Model Application allotted the Serial Number 2007/0008.

To the prior art, also the contents of the following patent publications belong:
U.S. Pat. No 4,326,773-A
US-2002/0 124 842-A1, and
U.S. Pat. No. 4,571,812-A.

The patent publication U.S. Pat. No. 4,326,773-A shows and describes a cylinder-parabolic reflector in order to allow to focus incident sunbeams toward a focal axis, assigned to said cylinder.

FIG. 1 in said patent publication demonstrates a conventional reflector unit built up by a sheet-shaped metal material and made in one piece.

Here is mentioned that the reflecting surface (1) may become the subject of a deformation, under the impact of mechanical- and temperature-dependent forces, in spite of the fact that, in order to allow to counteract said forces, there have been inserted radially oriented stiffening means (2) and peripherically oriented stiffened means (3).

More particularly, it is taught that a pipe (4), connecting to the focal axis, is clamped by supporting means (5), active against the radially oriented stiffening means (2).

In FIG. 2 in said patent publication, it is shown and described a module, which, when co-ordinated with additional modules, should be able to form a complete solar energy concentrator.

Here, a concave surface is made from a bright polished or processed aluminium sheet, having a thickness of 1 mm, while the other five details of the arrangement (6) are of stiffer materials.

Furthermore, it is taught that two aluminium pipes (7, 7′) are dimensioned, as inner and outer diameters, 18/20 mm in diameter as well as embedded in plastic foam.

The end areas (8, 8′) of the pipes (7 7′) are adapted to extend past the panel by a distance of 25 mm and having an outer diameter of 18 mm.

The narrower end areas (8, 8′) should, by means of press fit, be able to co-operate with the end areas (8a, 8a′) of homogeneous pipes or bars, of an adjacent panel (6a).

The aluminium sheet is angular along the opposed end areas thereof for the purpose of a stiffening effect.

The patent publication US-2002/0 124 842-A1 shows and describes a collecting unit for thermal rays.

Said unit has an enclosing member or box (1) having an open upper portion and a number of heat-reflecting modules (2), placed next to each other inside the box (1).

Each module (2) provides a heat-absorbing means (3), in the form of a pipe, as well as a reflector (4) in order to allow to reflect thermal rays toward the means (3).

The means (3) are co-ordinated with each other by means of connecting pipes (3a).

Open end areas of the box (1) should be closed by a plurality of glass units or another transparent material (5), so as to create a thermal insulation of the interior of the box (1).

More particularly, the patent publication teaches that the reflector (4) should be pressed by pressing plates and should be formed with a central edge (42b).

Here, it is furthermore taught that the reflector (42) should have a predetermined width dimension, so that when the reflector is pressed into the recess (41a) thereof, then the two edges thereof will be in a co-operation with corresponding parts (41b), wherein the reflector sheet will assume a selected set position due to its own bending ability.

The patent publication U.S. Pat. No. 4,571,812-A shows and describes a solar energy concentrator having a thin reflector sheet and having a bright polished or processed reflecting surface and which sheet should be supported by a rigid construction, shown in FIG. 5, including two elongate parts (14, 16) having a plurality of supporting and strengthening parts (18), which have been given a shape where at all events the interior surfaces (20) thereof are shaped with a configuration that connects to the parabolic shape, that should have the proper reflector material.

### SUMMARY OF THE PRESENT INVENTION

### Technical Problem

If attention is paid to the circumstance that the technical considerations that a person skilled in the relevant technical field has to do to be able to present a solution to one or more technical problems raised, are, on one hand, initially a necessary understanding of the measures and/or the sequence of measures that have to be taken, and on the other hand a necessary selection of the means that is/are required, then the subsequent technical problems would, in view of this, be relevant in the creation of the present subject matter of invention.

Therefore, in view of the prior art, as it has been described above, it should be seen as a technical problem to be capable of realizing the significance of, the advantages associated with and/or the technical measures and considerations that will be required to, in an arrangement adapted for an absorption of primarily heat arising from received sunbeams, and having a sunbeam-reflecting reflector unit faceable toward the sunbeams and a thermal and/or luminous energy-absorbing means related to the reflector unit, wherein said reflector unit and said absorbing means ought to be coverable by a transparent protection, besides which said reflector unit and primarily the reflector surface thereof should be formed from a thin and easily bendable material and in other respects have the characteristic features defined in the preamble of claim 1, be able to advice and afford a complete construction, that will be light in weight.

Therefore, in view of the prior art, as it has been described above, it should be seen as a technical problem to be capable of realizing the significance of, the advantages associated with and/or the technical measures and considerations that will be required to far-reachingly allow to reduce the requisite and required material contents of the solar cell and the solar energy concentrator as an entirety.

Therefore, in view of the prior art, as it has been described above, it should be seen as a technical problem to be capable of realizing the significance of, the advantages associated with and/or the technical measures and considerations that will be required to be able to advice and afford a limited area requirement of the solar cell and/or the solar energy concentrator at one and the same power output as a conventionally constructed solar cell or solar energy concentrator.

There is a technical problem to be capable of realizing the significance of, the advantages associated with and/or the technical measures and considerations that will be required in order to allowing said reflector unit to be adapted for a co-operation with a plurality of support members, in the following description denominated as “reflector springs”, distributed along a length-oriented or longitudinal extension of said reflector unit and across the reflector surface, and oriented perpendicularly to, or at all events substantially perpendicularly to, said longitudinal extension, in order to, in that connection, allow said reflector unit and the reflector surface thereof to, depending on a temperature influence, be able to deform within an elastic range applicable for a selected shape and/or choice of material, however while keeping a profile of a stable shape.

There is a technical problem to be capable of realizing the significance of, the advantages associated with and/or the technical measures and considerations that will be required in order to allowing said support members or reflector springs to have a curved shape, where each one of the same, or selected, reflector springs, is formed as a thin wire or a thin strip, in order to, in that connection, be able to afford a motion of the reflector surface and the carrier thereof related to occurring changes of temperature, however while keeping the same reflector shape of the surface or reflector surfaces reflecting the sunbeams.

There is a technical problem to be capable of realizing the significance of, the advantages associated with and/or the technical measures and considerations that will be required in order to allowing said reflector springs to be fixed and bent into a curved shape, in order to be able to keep the shape of the reflector surface within an optimum shape, adapted for a sunbeam reflection against the thermal and/or luminous energy-absorbing means.

There is a technical problem to be capable of realizing the significance of, the advantages associated with and/or the technical measures and considerations that will be required in order to allow to compensate for the occurring changes of temperature that will cause a motion or displacement of the reflector unit and primarily the reflector surface thereof in a longitudinal direction and extension.

There is a technical problem to be capable of realizing the significance of, the advantages associated with and/or the technical measures and considerations that will be required to provide for, for a supporting of the reflector unit and/or the reflector surface and the carrier or support portion thereof, the presence of longitudinal edges, in such a way that they follow a straight line, such as parallel lines, as well as, in order to give a support to said transparent protection, such as a glass or another covering plate, allow to provide for the utilization of a box-shaped container, a so-called ribbed box.

There is a technical problem to be capable of realizing the significance of, the advantages associated with and/or the technical measures and considerations that will be required in order to allowing the longitudinal edges of the ribbed box to have one or more notches, adapted for a co-operation with co-ordinatable longitudinal edges.

There is a technical problem to be capable of realizing the significance of, the advantages associated with and/or the technical measures and considerations that will be required in order to allowing such a ribbed box to be formed from a light weighted material, such as wood material and/or a composite material.

There is a technical problem to be capable of realizing the significance of, the advantages associated with and/or the technical measures and considerations that will be required in order to allowing said reflector springs to be adapted to closely connect to and support the reflector surface as well as connect as a support of said thermal and/or luminous energy-absorbing means.

There is a technical problem to be capable of realizing the significance of, the advantages associated with and/or the technical measures and considerations that will be required in order to allowing a concentration factor, assigned to the reflector unit and particularly the reflector surface, to be selected within an adapted range, such as falling within the factor values of between 4.0 to 3.0.

There is a technical problem to be capable of realizing the significance of, the advantages associated with and/or the technical measures and considerations that will be required in order to allowing an orientation of the reflector unit including the reflector surface thereof and said thermal and/or luminous energy-absorbing means to be mutually adapted in such a way that an incident sunlight and sunlight beams, upon a low solstice, can be focused toward one edge of the means as well as, upon a high solstice, can be focused toward another edge of the means or vice versa.

There is a technical problem to be capable of realizing the significance of, the advantages associated with and/or the technical measures and considerations that will be required in order to allowing said ribbed box to be fixedly fitted to a fixed base.

There is a technical problem to be capable of realizing the significance of, the advantages associated with and/or the technical measures and considerations that will be required in order to allowing the curve shape of the reflector surface, in cross-section and along the reflector springs, to be adapted to connect to a function corresponding to a “CPC”-function (“Compound Parabolic Concentrator”).

There is a technical problem to be capable of realizing the significance of, the advantages associated with and/or the technical measures and considerations that will be required to provide a longitudinal or length-oriented support profile next to one of the length-oriented edges of the reflector unit and/or the reflector surface, facing away from the thermal and/or luminous energy-absorbing means.

There is a technical problem to be capable of realizing the significance of, the advantages associated with and/or the technical measures and considerations that will be required in order to allowing each one of said reflector springs to have an angled portion or an angled extension, oriented next to or adjacent to said support profile.

There is a technical problem to be capable of realizing the significance of, the advantages associated with and/or the technical measures and considerations that will be required in order to allowing said reflector surface and said carrier and/or support portion to be integratedly formed with each other.

There is a technical problem to be capable of realizing the significance of, the advantages associated with and/or the technical measures and considerations that will be required in order to allowing said reflector springs to be adapted to rest against the reflecting surface and the carrier thereof, with a varying bearing pressure.

There is a technical problem to be capable of realizing the significance of, the advantages associated with and/or the technical measures and considerations that will be required in order to allowing an intermediately oriented or lowermost part assigned to the reflector spring to be adapted to absorb a greatest pressure or a greater pressure than the end portions of the reflector spring.

There is a technical problem to be capable of realizing the significance of, the advantages associated with and/or the technical measures and considerations that will be required in order to allowing the end portions to be adapted to create a small or no bearing pressure at all.

### The Solution

In that connection, the present invention starts out from the known technique provided by way of introduction and is based on an arrangement adapted for an absorption of primarily thermal and/or luminous energy arising from received sunbeams, and having a sunbeam-reflecting reflector unit faceable toward the sunbeams and a thermal and/or luminous energy-absorbing means related to the reflector unit, wherein said reflector unit and said thermal and/or luminous energy-absorbing means ought to be coverable by a transparent protection, said reflector surface and the carrier or support portion thereof being formed from a thin and easily bendable material.

The invention is furthermore based on that said reflector unit and primarily the reflector surface thereof should be adapted for a co-operation with a plurality of support members, distributed along a length-oriented or longitudinal extension of said reflector unit.

Under the reflector surface thereof and oriented perpendicularly to, or at all events substantially perpendicularly to, said longitudinal extension, said support members are present, in order to allow said reflector unit and/or said reflector surface to, depending on a temperature influence, be able to deform within an elastic range applicable for a selected shape and/or choice of material, however while keeping a profile in a stable shape.

In order to be able to solve one or more of the above-mentioned technical problems, the present invention particularly teaches that the thus known technique should be supplemented in that, in addition to said support members, further support members are provided, where the latter support members should be given the form of reflector springs and adapted to rest against the reflecting surface of the reflector unit or the reflector surface thereof, each one of said support members or reflector springs being formed as a thin wire or a thin strip, in order to be able to afford a motion of the reflector unit, and/or the reflector surface thereof, related to changes of temperature while keeping the same reflector shape of the sunbeam-reflecting surface.

As proposed embodiments, falling within the scope of the fundamental idea of the present invention, moreover it is taught that said reflector springs here should be bent into a curved shape, adapted to the curvature of the reflector surface, in order to be able to keep the reflector surface within an optimum shape, adapted for a sunbeam reflection against the thermal and/or luminous energy-absorbing means.

The invention provides the possibility of being able to compensate for the motions of the reflector unit, and particularly with the reflector surface thereof in a longitudinal extension, caused by changes of temperature.

For a supporting of the longitudinal edges of the reflector unit or the reflector surface, in such a way that they follow a straight line, such as parallel lines, as well as to give a support to said transparent protection, such as a glass or another covering plate, there is provided for the utilization of a box-shaped container, a so-called ribbed box, advantageously of a nature that is shown in the Swedish Utility Model Registration outlined initially.

The longitudinal edges of the ribbed box should then have notches, adapted for a co-operation with co-ordinatable longitudinal edges for a relative displacement depending on temperature variations.

Here, the ribbed box should be able to be formed from a wood material and/or a composite material.

Said reflector springs should be adapted to, on one hand, connect closely to the reflector surface, advantageously with a varying bearing pressure, and on the other hand connect as a support of said thermal or luminous energy-absorbing means.

A concentration factor, assigned to the reflector unit, ought to be selected within a range of 4.0 to 3.0.

The orientation of the reflector unit including the reflector surface thereof and said thermal and/or luminous energy-absorbing means may mutually be adapted in such a way that an incident sunlight, upon a high solstice, will be focused toward one edge of the means as well as, upon a low solstice, will be focused toward the other edge of the means or vice versa.

Said ribbed box may advantageously be fixedly fitted to a fixed base.

The curve shape of the reflector surface, in cross-section and along the reflector springs, is adapted to connect to a function corresponding to a “CPC”-unit (Compound Parabolic Concentrator).

Next to one of the length-oriented edges of the reflector unit, facing from the thermal and/or luminous energy-absorbing means, there is present a longitudinal support profile.

Each one of said reflector springs should furthermore have an angled portion or an angled extension, oriented next to said support profile.

Said reflector surface and said carrier and/or support portion may be integrated with each other.

Particularly, it is taught that said reflector springs may be adapted to rest against the reflecting surface and the carrier thereof with a varying bearing pressure in such a way that an intermediately oriented or lowermost part assigned to the reflector spring will be adapted to absorb a greatest pressure or greater pressure than the end portions of the reflector spring, where the end portions are adapted to a small or no bearing pressure.

### Advantages

The advantages that foremost may be regarded as characteristic of the present invention and the special significative features provided thereby are that, in this way, conditions have been created in order to, in an arrangement adapted for an absorption of primarily thermal and/or luminous energy arising from received sunbeams, and having a sunbeam-reflecting reflector unit faceable toward the sunbeams and a thermal and/or luminous energy-absorbing means related to the reflector unit, said reflector unit and said thermal and/or luminous energy-absorbing means being coverable by a transparent protection, said reflector unit and primarily the reflector surface thereof including appurtenant carrier or support portion being formed from a thin and easily bendable material, allow to provide for that the reflector surface of said reflector unit and the carrier thereof should be adapted for a co-operation with a plurality of upper support members oriented side by side, denominated reflector springs, distributed along a length-oriented or longitudinal extension of said reflector unit, and oriented perpendicularly to, or at all events substantially perpendicularly to, said longitudinal extension, in order to allow said reflector unit including the assigned reflector surface thereof to, depending on a temperature influence, be able to deform within an elastic range applicable for a selected shape and/or choice of material, however while keeping a reflection profile of stable shape.

What foremost can be regarded as characteristic of the present invention is defined in the characterizing clause of the subsequent claim 1.

### BRIEF DESCRIPTION OF THE DRAWINGS

A presently proposed embodiment, having the significative features associated with the present invention, will now, for the purpose of exemplifying, be described more in detail, reference being made to the accompanying drawing, wherein:

FIG. 1 shows in a perspective presentation a plurality of identical arrangements, in accordance with the provisions of the present invention, oriented in rows and columns,

FIG. 2 shows in a cross-section two adjacent arrangements in order to allow to illustrate a calculation of a concentration factor as well as allow to illustrate a range of acceptance angle of the incident sunbeams,

FIG. 3 shows in an enlarged view a one, a first, interior end section of an arrangement having an inserted reflector spring,

FIG. 4 shows in cross-section one of the edge portions of an arrangement having a reflector spring introduced, which is intended to press the reflector surface against the carrier and support portion thereof with a selected curvature of the reflector surface, and

FIG. 5 shows in an enlarged view another, in relation to in FIG. 3, opposed end section of the arrangement.

### DESCRIPTION OF A PRESENTLY PROPOSED EMBODIMENT

Then, by way of introduction, it should be emphasised that in the subsequent description of a presently proposed embodiment, exhibiting the significant features associated with the invention and being elucidated by the figures illustrated in the subsequent drawings, we have selected terms and a particular terminology with the purpose of, in that connection, first of all allowing to make evident the inventive idea.

It should, however, in this connection be taken into consideration that expressions selected here should not be seen as limiting solely to the terms utilized and selected here, but it should be understood that each term selected in this manner should be interpreted so that it, in addition, will be able to comprise all technical equivalents operating in the same or substantially the same way, in order to, in this way, enable the achievement of the same or substantially the same intention and/or technical effect.

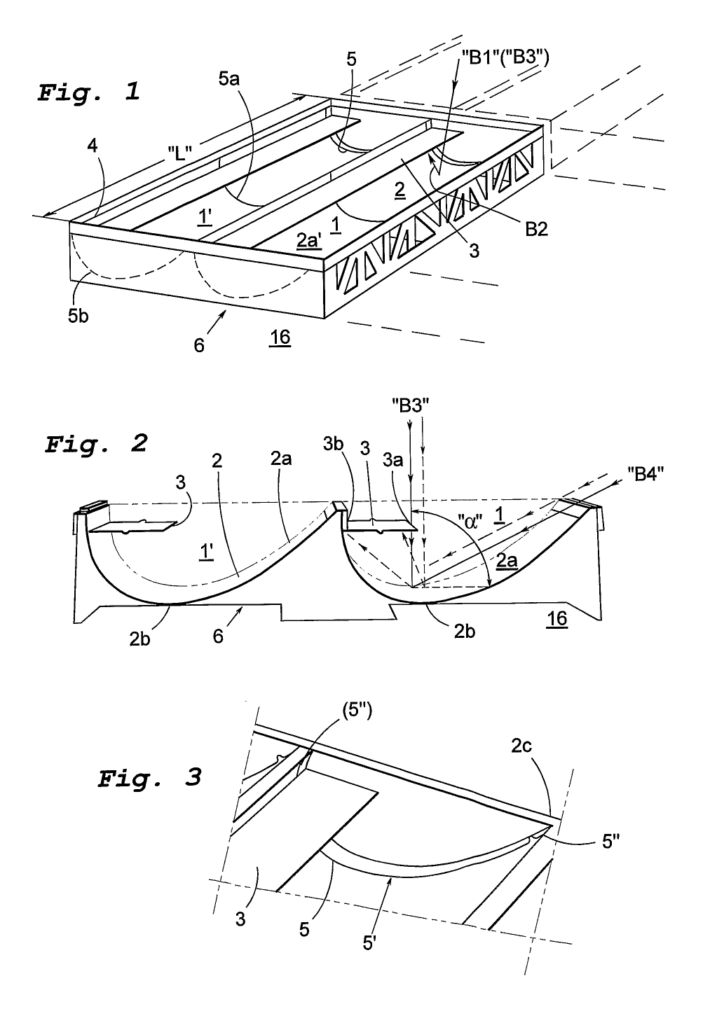

Thus, with a reference to the appended FIGS. 1 to 5, the fundamental conditions of the present invention are shown schematically and in detail, and where the significative peculiarities associated with the invention have been made concrete, by the presently proposed embodiment, described more in detail in the following.

Accordingly, FIG. 1 shows an arrangement 1 adapted for an absorption of primarily thermal and/or luminous energy arising from received sunbeams “B1” and reflected sunbeams “B2”, and having a sunbeam-reflecting reflector unit 2 faceable toward the sunbeams and a thermal and/or luminous energy-absorbing means 3 related to the reflector unit 2, said reflector unit 2 including a reflector surface 2a thereof and said thermal and/or luminous energy-absorbing means 3 being coverable by a protection 4, transparent to sunlight and serving as a mechanical coverage.

FIG. 1 illustrates a plurality of identical arrangements, and therefore, in the following, the invention will only be described to comprise two of said arrangements 1, 1′.

Said reflector unit 2 and particularly the reflector surface 2a thereof is formed from a thin and easily bendable material and carriers 2b or support portions are supporting the low-weight reflector surface 2a.

The reflector surface 2a may be oriented on an aluminium foil, having a thickness of, say 0.3 to 0.8 mm, with one surface of the aluminium foil being prepared to present high-reflective properties.

The proper reflector surface 2a may, however, be bright polished or in another way high-mirror finished via other methods to be able to exhibit said pronounced light-reflecting properties.

Here, the reflector surface 2a is supported by an aluminium foil, as a carrier 2b, formed from a thin bendable material.

Here, the present invention suggests that said carrier 2b is assigned the form of a metal sheet, having a thickness of between 0.2 and 1.5 mm.

Said reflector unit 2 and particularly the carrier 2b should be adapted for a co-operation with a plurality of discrete superjacent support members 5, here denominated “reflector springs”.

These should then be distributed along a length-oriented or longitudinal extension of said reflector unit 2 and oriented perpendicularly to, or at all events substantially perpendicularly to, said longitudinal extension “L”, in order to allow said reflector unit 2 including the reflector surface 2a and carrier 2b thereof to, depending on a temperature influence, be able to deform within an elastic range applicable for selected shape and/or a choice of material, however while keeping a profile of a stable shape.

Each one of said support members or reflector springs 5, 5a and 5b is formed as a thin wire or a thin strip, in order to be able to afford a motion or displacement of the reflector unit 2, and the reflector surface 2a thereof including carrier 2b, related to changes of temperature, while keeping the same reflector shape of the sunbeam-reflecting surface.

Said reflector springs 5, 5a, 5b are permanently bent into a curved shape, in order to be able to keep the reflector surface 2a and the carrier 2b thereof within an optimum shape, adapted for a sunbeam reflection towards and against the thermal and/or luminous energy-absorbing means 3.

The changes of temperature that are to be expected cause primarily a motion or displacement of the reflector unit 2 including the reflector surface 2a thereof in a longitudinal extension “L”.

For a supporting of the longitudinal edges of the reflector unit 2, such as the edge 2c, in such a way that they follow a straight line, such as parallel lines, as well as in order to give a support to said transparent protection 4, such as a glass or another covering plate, there is provided for the utilization of a box-shaped container 6, a so-called ribbed box.

The longitudinal edges of the ribbed box 6 have notches, adapted for a co-operation with co-ordinatable longitudinal edges of the reflector unit 2 and/or the edges of the reflector surface 2a.

The ribbed box 6 is normally formed from a wood material and/or a composite material.

Said reflector springs 5, 5a, 5b are adapted to, on one hand, connect to the reflector surface 2a, and on the other hand connect as a support of said thermal and/or luminous energy-absorbing means 3.

Here, the invention teaches that said reflector springs 5, 5a, 5b should support the reflector surface 2a against the carrier 2b thereof with a varying bearing pressure. More particularly, it is taught that the lowermost part 5′ of the reflector spring 5 should absorb or withstand the greatest pressure while the end portions 5″, (5″) of the reflector spring 5 should have a small or no bearing pressure.

A concentration factor “c” assigned to the reflector unit 2 and the reflector surface 2a is selected within the range of 4.0 to 3.0, where FIG. 2, with selected indications of measure, suggests a value of 3.34.

The orientation of the reflector unit 2 including the reflector surface 2a thereof and said thermal and/or luminous energy-absorbing means 3 are mutually adapted in such a way that an incident sunlight beam “B3”, upon a high solstice (zenith), will be focused toward the front (right) edge 3a of the means 3, as well as the incident sunlight beam “B4”, upon a low solstice, will be focused toward the rear (left) edge 3b of the means 3 with an angle range “a” of 90° to 30°.

Said ribbed box 6 should then primarily be fixedly fitted to a fixed base 16 via selected means known per se.

The curve shape of the reflector surface 2a, in cross-section and along the reflector springs 5, 5a, 5b, is adapted to connect to a function corresponding to a “CPC”-structure (Compound Parabolic Concentrator).

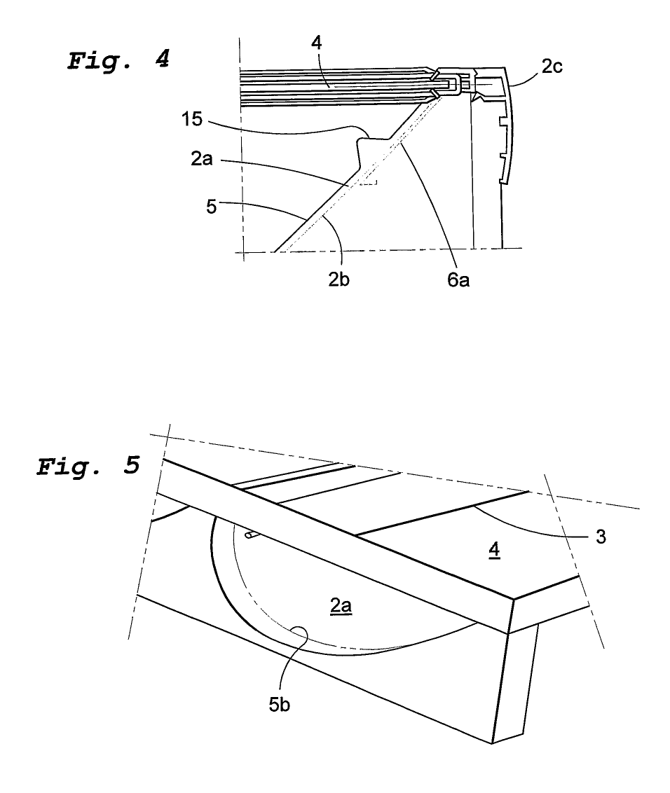

Next to one 2c of the length-oriented edges of the reflector unit 2, facing from the thermal and/or luminous energy-absorbing means 3, there is present a longitudinal support profile 6a (FIG. 4).

Furthermore, it is suggested that each one of said reflector springs 5, 5a, 5b may have an angled portion 15 or an angled extension, oriented next to said support profile 6a in order to surely allow to decrease the bearing pressure exerted here.

The invention is of course not limited to the embodiment given above as example, but may be subjected to modifications within the scope of the general idea according to the invention, illustrated in the subsequent claims.

Particularly, it should be taken into consideration that each unit and/or category shown can be combined with any other unit and/or category shown within the scope in order to be able to attain the desired technical function.

1. Arrangement adapted for an absorption of primarily thermal and/or luminous energy arising from received sunbeams, and having a sunbeam-reflecting reflector unit faceable toward the sunbeams and a thermal and/or luminous energy-absorbing means related to the reflector unit, said reflector unit and said thermal and/or luminous energy-absorbing means (3) being coverable by a transparent protection, the reflector surface of said reflector unit being formed from a thin and easily bendable material, besides which said reflector unit and primarily the reflector surface thereof is adapted for a co-operation with a plurality of support members, distributed along a length-oriented or longitudinal extension of said reflector unit and oriented under the reflector surface thereof as well as oriented perpendicularly to, or at all events substantially perpendicularly to, said longitudinal extension, in order to allow said reflector unit and/or said reflector surface to, depending on a temperature influence, be able to deform within an elastic range applicable for a selected shape and/or a choice of material, however while keeping a profile of a stable shape, wherein in addition to said lower support members, there are present further support members, where the latter support members are given the form of reflector springs and adapted to rest against the reflecting surface of the reflector unit or the reflector surface thereof, that each one of said further support members or reflector springs is formed as a thin wire or a thin strip, in order to be able to afford a motion or displacement of the reflector unit, and/or the reflector surface thereof, related to changes of temperature, while keeping the same reflector shape of the sunbeam-reflecting surface.

2. Arrangement according to claim 1, wherein each of said reflector springs is bent into a curved shape, in order to be able to keep the reflecting surface within an optimum shape, adapted for a sunbeam reflection against the thermal and/or luminous energy-absorbing means.

3. Arrangement according to claim 1, wherein occurring changes of temperature are adapted to cause primarily a motion of the reflector unit including the reflecting surface and/or reflector surface thereof in a longitudinal extension.

4. Arrangement according to claim 1, wherein for a supporting of the longitudinal edges of the reflector unit, in such a way that they can follow a straight line, such as parallel edges or lines, as well as in order to give a support to said transparent protection, such as a glass or another covering plate, there is provided for the utilization of a container, formed into a box, a so-called ribbed box.

5. Arrangement according to claim 4, wherein longitudinal edges assigned to the ribbed box have notches, adapted for a co-operation with co-or-dinatable longitudinal edges of the reflecting surface or the reflector surface.

6. Arrangement according to claim 4, wherein the ribbed box is formed from a wood material and/or a composite material.

7. Arrangement according to claim 1, wherein each of said reflector springs is adapted to, on one hand, connect to and rest against the reflecting surface, and on the other hand connect as a support of said thermal or luminous energy-absorbing means.

8. Arrangement according to claim 1, wherein a concentration factor assigned to the reflector unit is selected to fall within the range of 4.0 to 3.0.

9. Arrangement according to claim 1, wherein the orientation of the reflector unit including the reflector surface thereof and said thermal and/or luminous energy-absorbing means are mutually adapted in such a way that an incident sunlight beam, upon a low solstice, is focused toward one edge of the means, as well as, upon a high solstice, is focused toward the other edge of said means.

10. Arrangement according to claim 4, wherein said ribbed box is fixedly fitted to a fixed base.

11. Arrangement according to claim 1, wherein a curve shape of the reflecting surface, as viewed in cross-section and along the reflector springs, is adapted to connect to a function corresponding to a “Compound Parabolic Concentrator”.

12. Arrangement according to claim 1, wherein next to one of the length-oriented edges of the reflector unit, facing from the thermal and/or luminous energy-absorbing means, there is present a longitudinal support profile.

13. Arrangement according to claim 1, wherein each one of said reflector springs has an angled portion or an angled extension, oriented next to said support members.

14. Arrangement according to claim 12, wherein said reflector surface and said carrier and/or support portion are integrated with each other.

15. Arrangement according to claim 1, wherein said reflector springs are adapted to rest against the reflecting surface with a varying bearing or pressing pressure.

16. Arrangement according to claim 1, wherein an intermediately oriented or lowermost part, assigned to the reflector spring, is adapted to absorb or withstand a greatest pressure or greater pressure than the end portions of the reflector spring.

17. Arrangement according to claim 16, wherein the end portions are adapted to a small or no bearing pressure.

18. Arrangement according to claim 15, wherein an intermediately oriented or lowermost part, assigned to the reflector spring, is adapted to absorb or withstand a greatest pressure or greater pressure than the end portions of the reflector spring.
